(19) United States
(12) Patent Application Publication
(10) Pub. No.: US 2025/0120101 A1
(43) Pub. Date: Apr. 10, 2025

(54) TRENCH MOAT DECOUPLING CAPACITOR

(71) Applicant: INTERNATIONAL BUSINESS MACHINES CORPORATION, ARMONK, NY (US)

(72) Inventors: Herbert Lei Ho, Medfield, MA (US); Brent A. Anderson, Jericho, VT (US); John W. Golz, Hopewell Junction, NY (US)

(21) Appl. No.: 18/481,271

(22) Filed: Oct. 5, 2023

(51) Int. Cl. H10D 1/00

(52) U.S. Cl. CPC H10D 1/042; H10D 1/716

(57) ABSTRACT

Embodiments of present invention provide a capacitor structure. The capacitor structure includes a moat capacitor embedded in a substrate. The moat capacitor includes a bottom electrode plate; a dielectric layer directly above and lining the bottom electrode plate; and a top electrode plate directly above and lining the dielectric layer, where the bottom electrode plate, the dielectric layer, and the top electrode plate have encircling shapes and are arranged to be concentric with one another. A method of forming the same is also provided.

### BACKGROUND

The present application relates to manufacturing of semiconductor integrated circuits. More particularly, it relates to decoupling capacitor and method of making the same.

As semiconductor industry moves towards smaller node, for example 7-nm node and beyond, field-effect-transistors (FETs) are aggressively scaled to fit into reduced footprint or real estate. In the meantime, more logic and/or memory devices are packed into smaller areas for increased device density.

It is generally known in the art that in order to reduce and possibly avoid interference among closely packed devices, such as transistors, there is a need to properly insulate and/or decouple these devices. Conventionally, discrete trench capacitors have been used to decouple devices. However, due to the nature of being formed from discrete deep trenches, the relatively short spacing of the trenches and lack of contact area to the bottom plate of the trenches may limit the path of flow of electrons. As a result, a conventional trench capacitor based on discrete deep trenches typically has high serial resistance associated therewith.

### SUMMARY

Embodiments of present invention provide a capacitor structure. The capacitor structure includes a moat capacitor embedded in a substrate. The moat capacitor includes a bottom electrode plate; a dielectric layer directly above and lining the bottom electrode plate; and a top electrode plate directly above and lining the dielectric layer, where the bottom electrode plate, the dielectric layer, and the top electrode plate have encircling shapes and are arranged to be concentric with one another.

In one embodiment, the top electrode plate has a U-shaped cross-section; the dielectric layer surrounds a bottom and sides of the top electrode plate; and the bottom electrode plate surrounds a bottom and sides of the dielectric layer.

In another embodiment, the moat capacitor further includes a filler layer on top of the top electrode plate, the filler layer filling a space between an inner edge and an outer edge of the top electrode plate.

According to one embodiment, the capacitor structure further includes a capping layer above the substrate and the moat capacitor, a first set of contacts embedded in the capping layer in contact with the top electrode plate and a second and a third set of contacts embedded in the capping layer in contact with an inner edge and an outer edge respectively of the bottom electrode plate.

In one embodiment, the encircling shape of the dielectric layer is a square shape and the moat capacitor has a length and a width, where the length is at least 10 times larger than the width.

In another embodiment, the dielectric layer has a U-shaped cross-section and the moat capacitor has a depth and a width, where the depth is at least 25 times larger than the width.

According to another embodiment, where the moat capacitor is a first moat capacitor, the capacitor structure further includes a second moat capacitor nested inside the first moat capacitor, where the second moat capacitor has a bottom electrode plate that merges with the bottom electrode plate of the first moat capacitor.

According to another embodiment, the capacitor structure further includes an isolation trench embedded in the substrate, where the isolation trench encircles the moat capacitor and has a depth that is larger than a depth of the moat capacitor.

Embodiments of present invention also provide a method of forming a capacitor structure. The method includes forming a moat capacitor in a substrate by creating a moat-shaped trench opening in the substrate; doping regions of the substrate adjacent to a surface of the moat-shaped trench opening to form a bottom electrode plate; depositing a dielectric layer on top of the bottom electrode plate in the moat-shaped trench opening; and depositing a top electrode layer on top of the dielectric layer.

In one embodiment, the method further includes filling a remaining portion of the moat-shaped trench opening with amorphous silicon to form a filler layer; and forming a landing pad of metal silicide on top of the filler layer, where the landing pad is in contact with an inner edge and an outer edge of the top electrode plate.

In another embodiment, the method further includes forming a capping layer covering the moat capacitor and the substrate; forming a first set of contacts in the capping layer in contact with the top electrode plate; and forming a second and a third contacts in the capping layer in contact with an inner edge and an outer edge of the bottom electrode plate.

In yet another embodiment, the method further includes forming an isolation trench in the substrate, the isolation trench surrounding the moat capacitor and have a depth that is deeper than a depth of the moat capacitor.

In one embodiment, the moat capacitor is a first moat capacitor and the method further include forming a second moat capacitor nested inside the first moat capacitor, where the second moat capacitor has a bottom electrode plate that merges with the bottom electrode plate of the first moat capacitor.

### BRIEF DESCRIPTION OF THE DRAWINGS

The present invention will be understood and appreciated more fully from the following detailed description of embodiments of present invention, taken in conjunction with accompanying drawings of which:

FIGS. 1A and 1B are demonstrative illustrations of a top view and a cross-sectional view of a decoupling capacitor structure according to one embodiment of present invention;

FIGS. 2A and 2B are demonstrative illustrations of a top view and a cross-sectional view of a decoupling capacitor structure according to another embodiment of present invention;

FIGS. 3A and 3B are demonstrative illustrations of a top view and a cross-sectional view of a decoupling capacitor structure according to yet another embodiment of present invention;

FIGS. 4A, 4B, 4C, and 4D are demonstrative illustrations of cross-sectional views of a decoupling capacitor structure in a process of manufacturing thereof according to one embodiment of present invention; and

FIG. 5 is a demonstrative illustration of a flow-chart of a method of manufacturing a decoupling capacitor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

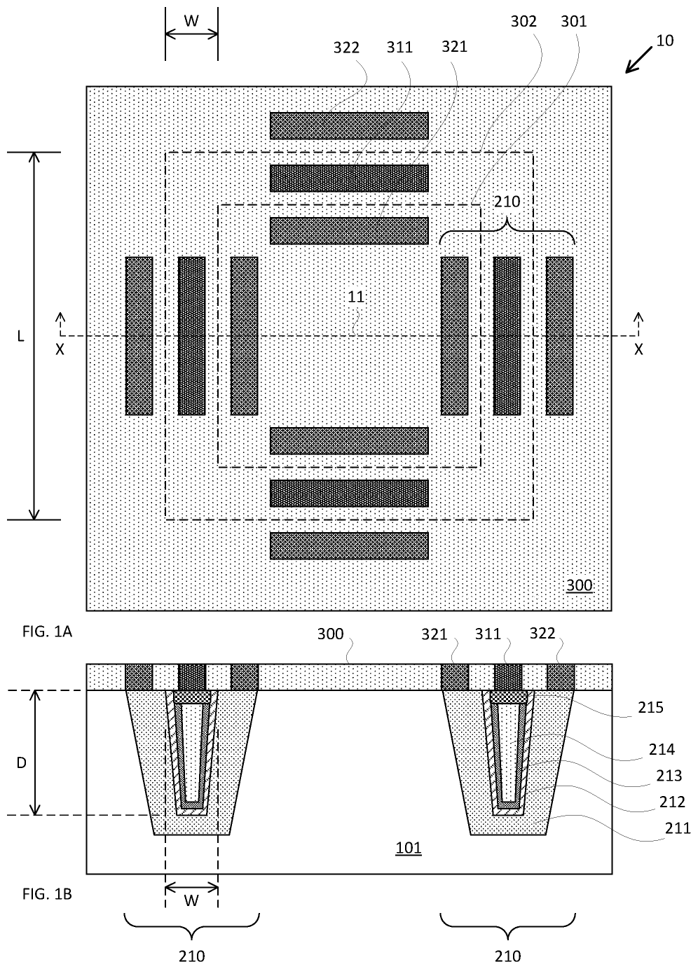

FIGS. 1A and 1B are demonstrative illustrations of a top view and a cross-sectional view respectively of a capacitor structure according to one embodiment of present invention. More particularly, embodiments of present invention provide a capacitor structure 10, and the capacitor structure 10 may be formed in a substrate 101 such as, for example, a silicon (Si) substrate, a silicon-germanium (SiGe) substrate, a silicon-on-insulator (SOI) substrate, or other suitable semiconductor substrate. The capacitor structure 10 may be used for decoupling purpose and thus may be referred to as a decoupling capacitor structure as well.

The capacitor structure 10 may include a bottom electrode plate 211 formed in an encircling shape; a dielectric layer 212 directly on top of and formed along the bottom electrode plate 211; and a top electrode plate 213 directly on top of and formed along the dielectric layer 212. The bottom electrode plate 211 may be a semiconductor layer such as, for example, a Si layer and may be heavily, and conformally, doped with either negative or positive dopants such as, for example, boron (B) or phosphorus (P). The bottom electrode plate 211 may be embedded in the substrate 101 and may have a U-shaped cross-section as is demonstratively illustrated in FIG. 1B, which is taken at a location denoted by the dashed line X-X. The dielectric layer 212 may be a thin dielectric film of, for example, silicon-nitride (SiN), silicon-oxide (SiO₂), hafnium-oxide (HfO₂), hafnium-silicon-oxide (HfSiO₂), or other suitable material. The thin dielectric film may line the bottom electrode plate 211 of U-shaped cross-section and may be formed along the encircling shape of the bottom electrode plate 211 to have a U-shaped cross-section and an encircling shape as well. Preferably, the dielectric layer 212 may have a high permittivity for improved capacitance. The top electrode plate 213 may be a conductive film and may line the dielectric layer 212 of U-shaped cross-section and may be formed along the encircling shape of the dielectric layer 212 to have a U-shaped cross-section and an encircling shape as well. The top electrode plate 213 may be a metal film such as, for example, a film of titanium-nitride (TiN) that is able to withstand high temperature.

The capacitor structure 10 may also include a filler layer 214 that fills a trench formed by the top electrode plate 213. In other words, the filler layer 214 may fill an opening formed by the top electrode plate 213 between an inner edge and an outer edge of the top electrode plate 213. Hereinafter, an inner edge refers to an edge that is closer to the center of the capacitor structure such as, for example, a center 11 of the capacitor structure 10, and an outer edge refers to an edge that is further away from the center of the capacitor structure. The filler layer 214 may include amorphous silicon and/or other suitable material such as dielectric materials. A landing pad 215 may be formed on top of the filler layer 214. The landing pad 215 may preferable be an ohmic contact and constructed of metal silicide. The landing pad 215 may be in electric contact with the inner edge and the outer edge of the top electrode plate 213.

The capacitor structure 10 may further include a capping layer 300 on top of the substrate 101 and more particularly on top of the bottom electrode plate 211, the dielectric layer 212, the top electrode plate 213, and the landing pad 215. The landing pad 215 may be on top of the filler layer 214 and in contact with both the inner and the outer edge of the top electrode plate 213. The capping layer 300 may include one or more sets of contacts in contact with the top electrode plate 213 via the landing pad 215, and in contact with the bottom electrode plate 211. For example, a first set of contacts 311 may be formed in contact with the landing pad 215; a second set of contacts 321 may be formed in contact with an inner edge of the bottom electrode plate 211; and a third set of contacts 322 may be formed in contact with an outer edge of the bottom electrode plate 211, all being embedded in the capping layer 300.

As is demonstratively illustrated in FIG. 1A, the bottom electrode plate 211, the dielectric layer 212, and the top electrode plate 213 may have encircling shapes and may be arranged to be concentric with one another. The bottom electrode plate 211, the dielectric layer 212, and the top electrode plate 213 together form a moat-shaped trench capacitor, referred to herein as moat capacitor 210. The moat capacitor 210 surrounds an area that may include devices (not shown) that are insulated or to be insulated by the capacitor structure 10 from areas outside the moat capacitor 210.

The encircling shape of the dielectric layer 212 is demonstratively illustrated in FIG. 1A by a first dashed line 301 and a second dashed line 302, representing respectively the inner edge and the outer edge of the dielectric layer 212. A person skilled in the art will understand, by referencing to FIG. 1B, that the inner edge of the bottom electrode plate 211 may be inside the first dashed line 301 and the outer edge of the bottom electrode plate 211 may be outside the second dashed line 302. On the other hand, both the inner edge and the outer edge of the top electrode plate 213 may be between the first dashed line 301 and the second dashed line 302.

The encircling shapes of the bottom electrode plate 211, the dielectric layer 212, and the top electrode plate 213 may be shapes of circles, ovals, rectangles, or squares. The encircling shapes may have a perimeter with a total length that is at least 40 times larger than a width W of the moat capacitor 210. Here, width W of the moat capacitor 210 is defined as a width measured from the inner edge of the dielectric layer 212 to the outer edge of the dielectric layer 212 as is illustrated in FIG. 1A. The moat capacitor 210 also has a length L. For example, in one embodiment, the bottom electrode plate 211, the dielectric layer 212, and the top electrode plate 213 may be in encircling shapes of square. The length L of the moat capacitor 210 is defined as a length measured vertically from an outer edge of the dielectric layer 212 at the top of the square to an outer edge of dielectric layer 212 at the bottom of the square, as is illustrated in FIG. 1A. In addition, the moat capacitor 210 may have a depth D, which is defined herein as a depth of the dielectric layer 212 measured in the cross-section thereof. In one embodiment, the depth D of the moat capacitor 210 may be at least 25 times larger than the width W of the moat capacitor 210.

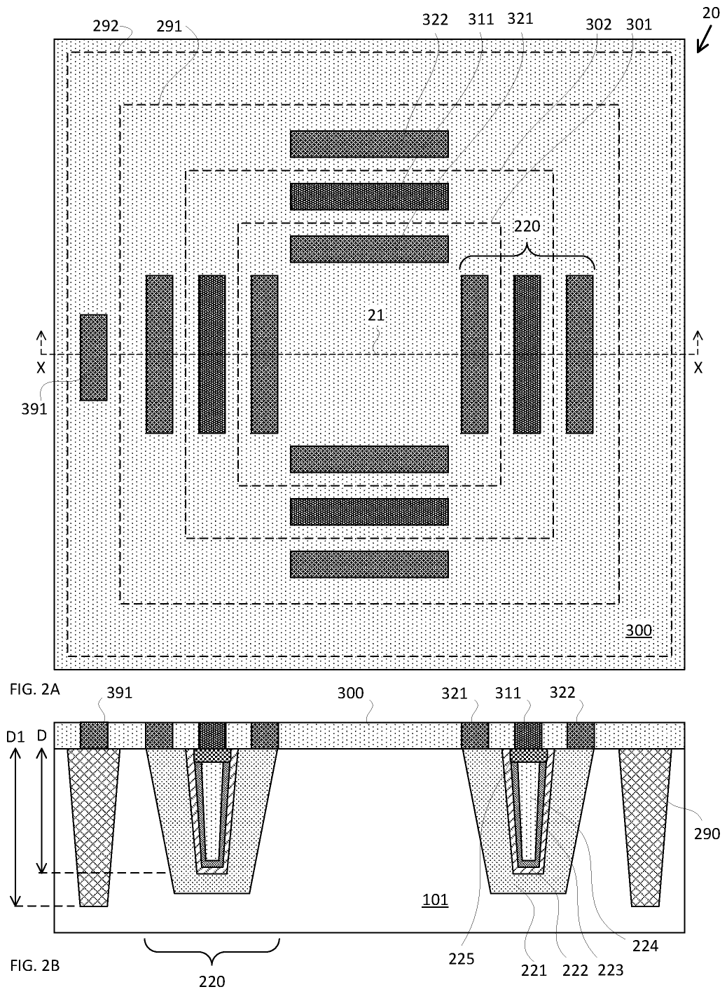

FIGS. 2A and 2B are demonstrative illustrations of a top view and a cross-sectional view respectively of a capacitor structure according to one embodiment of present invention. More particularly, embodiments of present invention provide a capacitor structure 20, which may be largely similar to the capacitor structure 10 illustrated in FIGS. 1A and 1B and may be referred to as a decoupling capacitor structure as well. For example, the capacitor structure 20 may include a moat capacitor 220 that includes a bottom electrode plate 221, a dielectric layer 222, a top electrode plate 223, a filler layer 224, and a landing pad 225. The capacitor structure 20 may also include a capping layer 300 with a first set of contacts 311, a second set of contacts 321, and a third set of contacts 322 embedded in the capping layer 300. The first, second, and third sets of contact 311, 321, and 322 may be formed to be in contact with the top electrode plate 223, via the landing pad 225, and in contact with the inner edge and outer edge of the bottom electrode plate 221 respectively. The inner edge and the outer edge of the bottom electrode plate 221 are relative to a center 21 of the capacitor structure 20.

Moreover, the capacitor structure 20 may further include an isolation moat or isolation trench 290 embedded in the substrate 101. As demonstratively illustrated in FIG. 2A by the dashed lines 291 and 292, the isolation trench 290 may be formed outside the bottom electrode plate 221, the dielectric layer 222, and the top electrode plate 223 to encircle the moat capacitor 220. The isolation trench 290 may have a depth D1 that is deeper than the depth D of the moat capacitor 220. The isolation trench 290 may be formed to be concentric with the moat capacitor 220 and may take the shape of a circle, an oval, a rectangle, or a square. However, embodiments of present invention are not limited in this aspect. The isolation trench 290 may have a different shape from the moat capacitor 220.

In one embodiment, one or more conductive contacts 391 may be formed to be in contact with the isolation trench 290, in particular when the substrate 101 is a silicon-on-insulator (SOI) substrate. The conductive contacts 391 of the isolation trench 290 may be grounded to present parasitic leakages of electrons to, for example, nearby devices and/or handling wafer.

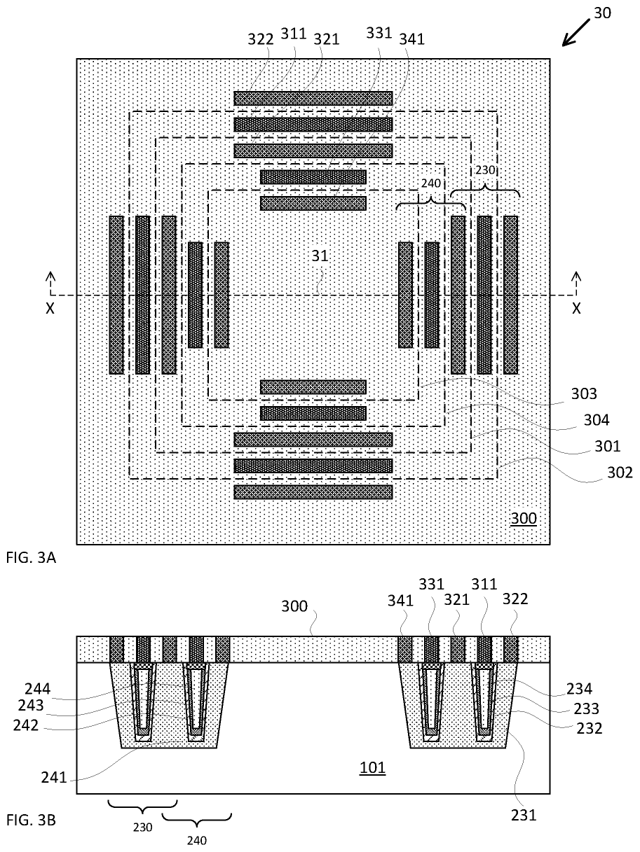

FIGS. 3A and 3B are demonstrative illustrations of a top view and a cross-sectional view respectively of a capacitor structure according to one embodiment of present invention. More particularly, embodiments of present invention provide a capacitor structure 30, which may include one or more nested moat capacitors such as a first moat capacitor 230 and a second moat capacitor 240. The second moat capacitor 240 may be nested inside the first moat capacitor 230. The capacitor structure 30 may be used for decoupling purpose and thus may be referred to as a decoupling capacitor structure as well.

The first moat capacitor 230 may include a bottom electrode plate 231, a dielectric layer 232, a top electrode plate 233, and a filler layer 234; and the second moat capacitor 240 may include a bottom electrode plate 241, a dielectric layer 242, a top electrode plate 243, and a filler layer 244. In one embodiment, the first and second moat capacitors 230 and 240 may be formed sufficiently close to each other such that the bottom electrode plate 231 may merge with the bottom electrode plate 241. In other words, the first and second moat capacitors 230 and 240 may share a common bottom electrode plate as is illustrated in FIG. 3B, which is a cross-sectional view at a location denoted by the dashed line X-X. In addition to the first, second, and third sets of contacts 311, 321, and 322, the capacitor structure 30 may also include a fourth set of contacts 331 in contact with the top electrode plate 243 of the second moat capacitor 240, and a fifth set of contacts 341 in contact with the inner edge, i.e., the edge closer to a center 31 of the capacitor structure 30, of the bottom electrode plate 241. The second moat capacitor 240 is illustratively indicated by the dashed lines 303 and 304 in FIG. 3A.

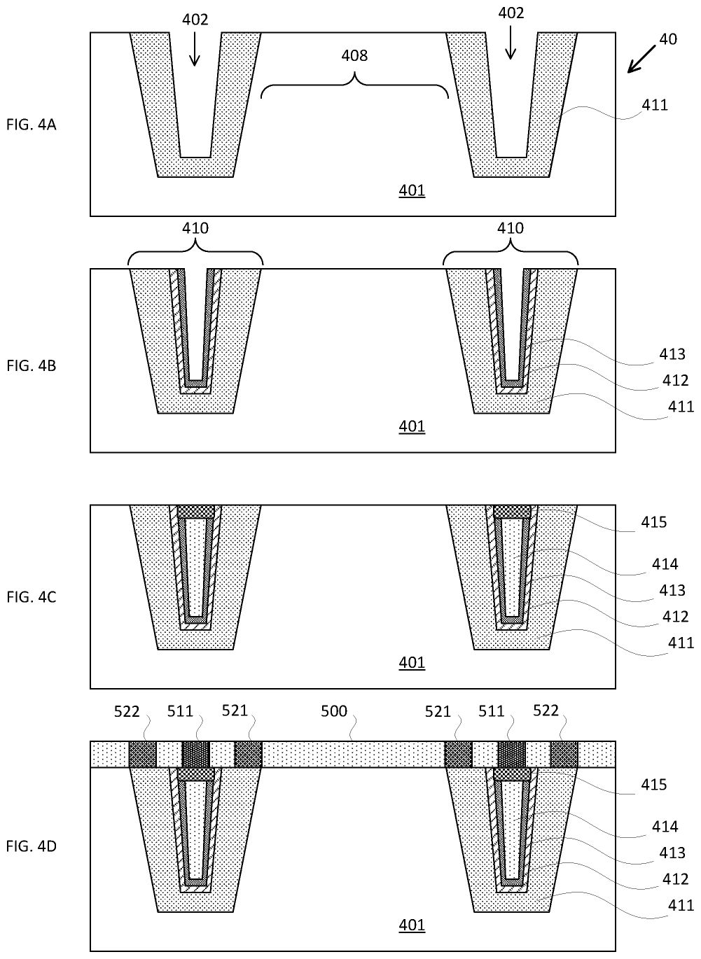

FIGS. 4A, 4B, 4C, and 4D are demonstrative illustrations of cross-sectional views of a capacitor structure in a process of manufacturing thereof according to one embodiment of present invention. More particularly, in forming a capacitor structure 40, embodiments of present invention provide receiving or providing a substrate 401 and create a moat-shaped trench opening 402 in the substrate through, for example, a lithographic patterning process. Next, the moat-shaped trench opening 402 may be heavily doped with either negative or positive dopant such as, for example, boron (B) or phosphorus (P) through an ion implantation process, thereby forming a moat-shaped bottom electrode plate 411 in the substrate 401. The moat-shaped bottom electrode plate 411 has a U-shaped cross-section and may surround an area 408 of the substrate 401 that is to be insulated or isolated from areas outside the moat-shaped bottom electrode plate 411. The substrate 401 may be a Si substrate, a SiGe substrate, a SOI substrate, or any other suitable substrate.

As is illustrated in FIG. 4B, embodiments of present invention further provide forming a dielectric layer 412 such as a dielectric film of SiN, SiO₂, HfO₂, or HfSiO₂ directly on top of the moat-shaped bottom electrode plate 411 through a deposition process. The deposition process may be, for example, a physical vapor deposition (PVD) process, a chemical vapor deposition (CVD) process, and/or an atomic layer deposition (ALD) process, and the formed dielectric layer 412 may line the moat-shaped bottom electrode plate 411. Embodiments of present invention may further provide forming a top electrode plate 413 by depositing a metal film such as, for example, a thin metal film of TiN lining the dielectric layer 412, thereby forming a moat capacitor 410.

As is illustrated in FIG. 4C, embodiments of present invention continue with filling any remaining portions of the moat-shaped trench opening 402 between an inner edge and an outer edge of the top electrode plate 413 with amorphous silicon (a-Si) to form a filler layer 414. The top electrode plate 413 may have a U-shaped cross-section as well following that of the moat-shaped bottom electrode plate 411. Next, a landing pad 415 may be formed at the top of the filler layer 414 by a silicide process of a metal layer on top of the filler layer 414. The landing pad 415 may be formed to be in electric contact with the inner edge and the outer edge of the top electrode plate 413.

Next, as is illustrated in FIG. 4D, a capping layer 500 such as a dielectric layer may be deposited on top of the substrate 401 covering the moat capacitor 410 that is embedded in the substrate 401. Subsequently, one or more sets of contacts may be formed in the capping layer 500. For example, a first set of contacts 511 may be formed to be in contact with the top electrode plate 413 via the landing pad 415, and a second and a third set of contacts 521 and 522 may be formed to be in contact with an inner edge and an outer edge, respectively, of the moat-shaped bottom electrode plate 411.

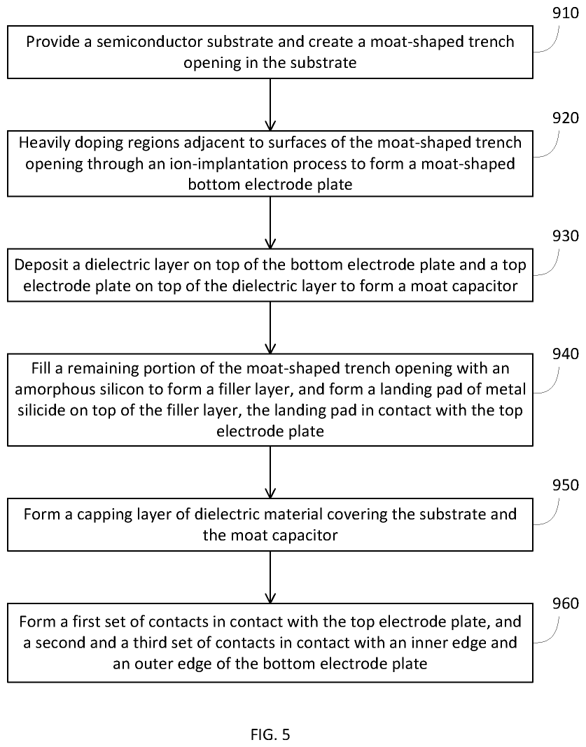

FIG. 5 is a demonstrative illustration of a flow-chart of a method of manufacturing a capacitor structure according to embodiments of present invention. The method includes (910) providing a semiconductor substrate and creating a moat-shaped trench opening in the substrate; (920) heavily doping regions adjacent to surfaces of the moat-shaped trench opening through an ion-implantation process to form a moat-shaped bottom electrode plate; (930) depositing a dielectric layer on top of the bottom electrode plate; and depositing a top electrode plate on top of the dielectric layer to form a moat capacitor; (940) filling remaining portions of the moat-shaped trench opening between an inner edge and an outer edge of the top electrode plate with an amorphous silicon to form a filler layer and optionally forming a landing pad of silicide on top of the filler layer to be in contact with the top electrode plate; (950) forming a capping layer of dielectric material covering the substrate and the moat capacitor; and (960) forming a first set of contacts contacting the top electrode plate and a second and a third set of contacts contacting an inner edge and an outer edge of the moat-shaped bottom electrode plate.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A capacitor structure comprising a moat capacitor embedded in a substrate, the moat capacitor includes:
a bottom electrode plate;
a dielectric layer directly above and lining the bottom electrode plate; and
a top electrode plate directly above and lining the dielectric layer,
wherein the bottom electrode plate, the dielectric layer, and the top electrode plate have encircling shapes and are arranged to be concentric with one another.

2. The capacitor structure of claim 1, wherein the top electrode plate has a U-shaped cross-section; the dielectric layer surrounds a bottom and sides of the top electrode plate; and the bottom electrode plate surrounds a bottom and sides of the dielectric layer.

3. The capacitor structure of claim 2, wherein the moat capacitor further includes a filler layer on top of the top electrode plate, the filler layer filling a space between an inner edge and an outer edge of the top electrode plate.

4. The capacitor structure of claim 1, further comprising a capping layer above the substrate and the moat capacitor, a first set of contacts embedded in the capping layer in contact with the top electrode plate and a second and a third set of contacts embedded in the capping layer in contact with an inner edge and an outer edge respectively of the bottom electrode plate.

5. The capacitor structure of claim 1, wherein the encircling shape of the dielectric layer is a square shape and the moat capacitor has a length and a width, wherein the length is at least 10 times larger than the width.

6. The capacitor structure of claim 1, wherein the dielectric layer has a U-shaped cross-section and the moat capacitor has a depth and a width, wherein the depth is at least 25 times larger than the width.

7. The capacitor structure of claim 1, wherein the moat capacitor is a first moat capacitor, further comprising a second moat capacitor nested inside the first moat capacitor, wherein the second moat capacitor has a bottom electrode plate that merges with the bottom electrode plate of the first moat capacitor.

8. The capacitor structure of claim 1, further comprising an isolation trench embedded in the substrate, wherein the isolation trench encircles the moat capacitor.

9. The capacitor structure of claim 8, wherein the isolation trench has a depth that is larger than a depth of the moat capacitor.

10. A method of forming a capacitor structure, the method comprising forming a moat capacitor in a substrate by:
creating a moat-shaped trench opening in the substrate;
doping regions of the substrate adjacent to a surface of the moat-shaped trench opening to form a bottom electrode plate;
depositing a dielectric layer on top of the bottom electrode plate in the moat-shaped trench opening; and
depositing a top electrode layer on top of the dielectric layer.

11. The method of claim 10, further comprising:
filling a remaining portion of the moat-shaped trench opening with amorphous silicon to form a filler layer; and
forming a landing pad of metal silicide on top of the filler layer,
wherein the landing pad is in contact with an inner edge and an outer edge of the top electrode plate.

12. The method of claim 10, further comprising:
forming a capping layer covering the moat capacitor and the substrate;
forming a first set of contacts in the capping layer in contact with the top electrode plate; and
forming a second and a third contacts in the capping layer in contact with an inner edge and an outer edge of the bottom electrode plate.

13. The method of claim 10, further comprising:
forming an isolation trench in the substrate, the isolation trench surrounding the moat capacitor and have a depth that is deeper than a depth of the moat capacitor.

14. The method of claim 10, wherein the moat capacitor is a first moat capacitor, further comprising:
forming a second moat capacitor nested inside the first moat capacitor, wherein the second moat capacitor has a bottom electrode plate that merges with the bottom electrode plate of the first moat capacitor.

15. A capacitor structure comprising a moat capacitor, the moat capacitor includes:
a bottom electrode plate formed in an encircling shape;
a dielectric layer directly above and formed along the bottom electrode plate; and
a top electrode plate directly above and formed along the dielectric layer.

16. The capacitor structure of claim 15, wherein the moat capacitor further includes a filler layer on top of the top electrode plate, filling a space between an inner edge and an outer edge of the top electrode plate, and a landing pad above the filler layer and in contact with the inner edge and the outer edge of the top electrode plate.

17. The capacitor structure of claim 16, further comprising a first set of contacts in contact with the top electrode plate via the landing pad, and a second and a third set of contacts in contact with an inner edge and an outer edge respectively of the bottom electrode plate.

18. The capacitor structure of claim 15, wherein the moat capacitor has a square shape and a length, a width, and a depth, wherein the length is at least 10 times larger than the width and the depth is at least 25 times larger than the width.

19. The capacitor structure of claim 15, wherein the moat capacitor is a first moat capacitor, further comprising a second moat capacitor nested inside the first moat capacitor, wherein the second moat capacitor has a bottom electrode plate that merges with the bottom electrode plate of the first moat capacitor.

20. The capacitor structure of claim 15, further comprising an isolation trench embedded in the substrate, wherein the isolation trench encircles the moat capacitor.
